(19) United States
(12) Patent Application Publication
(10) Pub. No.: US 2026/0196979 A1
(43) Pub. Date: Jul. 9, 2026

(54) Bandpass Filter, Multiplexer and Duplexer

(71) Applicant: Sanan Japan Technology Corporation, Kanagawa (JP)

(72) Inventors: Hitoshi Tsukidate, Kanagawa (JP); Takashi Ano, Kanagawa (JP); Shinichi SHIOI, Kanagawa (JP)

(21) Appl. No.: 19/430,208

(22) Filed: Dec. 22, 2025

(30) Foreign Application Priority Data
Dec. 25, 2024 (JP) 2024-229544

(51) Int. Cl. H03H 9/02

(52) U.S. Cl. CPC H03H 9/02574; H03H 9/02818; H03H 2009/02165

(57) ABSTRACT

A bandpass filter is disclosed, which includes a piezoelectric substrate and a plurality of resonators formed thereon and arranged to constitute the bandpass filter. Some resonators have a first thickness h1, others have a thinner thickness h2. A resonator whose anti-resonant frequency lies above the passband (outside the passband) and is closest to its high-frequency end has a thinner electrode layer thickness h2, thereby improving temperature characteristics and power durability while suppressing an increase in filter size.

### CROSS-REFERENCE TO RELATED APPLICATION

The present disclosure claims priority to Japanese Patent Application No. 2024-229544 filed Dec. 25, 2024, the contents of which are herein incorporated by reference in its entirety.

### FIELD

The present invention relates to a bandpass filter and a multiplexer including a plurality of resonators.

### BACKGROUND

For example, bandpass filters and multiplexers employing a plurality of surface acoustic wave (SAW) resonators are known as duplexers for mobile phones.

In Patent Document 1 (JP2018-101849A), there is disclosed an acoustic wave device including a plurality of IDT electrodes provided on a piezoelectric substrate and a dielectric film made of silicon oxide covering the plurality of IDT electrodes, wherein each of the plurality of IDT electrodes includes a first electrode layer mainly composed of Mo or W and a second electrode layer mainly composed of Cu. By configuring the device so that the thicknesses of the first and second electrode layers satisfy a predetermined formula, it is possible to stably and effectively widen the relative bandwidth of the acoustic wave device while improving the frequency-temperature characteristics, thereby improving the trade-off relationship between the relative bandwidth and the frequency-temperature characteristics found in conventional acoustic wave devices.

In Patent Document 2 (JP2001-267868A), a plurality of acoustic wave elements are disclosed which are provided on the same piezoelectric substrate and have electrode layers of different thicknesses for each acoustic wave element.

In bandpass filters and multiplexers using SAW resonators having IDT electrodes on a piezoelectric substrate, it is desired to improve the frequency-temperature characteristics to reduce the absolute value of their temperature dependence. If the absolute value of the temperature coefficient of frequency is large, changes in temperature may cause variations in transmission characteristics, leading to signal loss by cutting frequencies that should normally pass through. The increase in loss can cause heat generation, which lowers power durability.

### SUMMARY

Some examples described herein may have an object of providing a bandpass filter and a multiplexer capable of improving the temperature characteristics of resonators, reducing loss, and enhancing power durability, while suppressing an increase in the overall size of the bandpass filter and multiplexer.

In some examples, a bandpass filter is provided, which comprises a piezoelectric substrate; and a plurality of resonators formed on the piezoelectric substrate; wherein the plurality of resonators include IDT electrodes composed of electrode layers provided on the piezoelectric substrate; wherein the plurality of resonators include a first resonator having a first electrode layer thickness h1, and a second resonator having a second electrode layer thickness h2, wherein h2<h1; and, among the plurality of resonators, the resonator whose anti-resonant frequency lies on the higher-frequency side of the passband and is closest to the high-frequency end of the passband, has the electrode layer thickness h2.

In some examples, a multiplexer includes the above-mentioned bandpass filter.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a circuit configuration diagram of a transmit filter as a bandpass filter according to a first embodiment of the present invention.

FIG. 2 is a cross-sectional view showing a cross section of a resonator constituting the bandpass filter of the first embodiment of the present invention.

FIG. 3 is a top view of the resonator constituting the bandpass filter of the first embodiment of the present invention.

FIG. 4 is an enlarged cross-sectional view showing an enlarged portion of the electrode layer of the resonator constituting the bandpass filter of the first embodiment of the present invention.

FIG. 5 is a graph showing the temperature coefficient of frequency (TCF) corresponding to a change in the ratio of electrode layer thickness h/λ in a resonator having an electrode layer 5 formed on a piezoelectric layer 2 as shown in FIG. 2.

FIG. 6 is a graph showing attenuation versus frequency characteristics of the transmit filter functioning as the bandpass filter shown in FIG. 1, as well as transmission characteristics of each resonator.

FIG. 7 is a circuit configuration diagram of a transmit filter according to Example 6.

FIG. 8 is a circuit configuration diagram of a duplexer including the transmit filter of the first embodiment.

FIG. 9 is a circuit configuration diagram of a duplexer including a receiving filter 40 according to a third embodiment.

FIG. 10 is a circuit configuration diagram showing a duplexer according to a fourth embodiment.

FIG. 11 is a graph showing transmission characteristics of each resonator, a DMS, and a receiving filter 60 shown in FIG. 10.

FIG. 12 is a circuit configuration diagram of a transmit/receive (TRx) filter 400 according to a fifth embodiment.

FIG. 13 is a cross-sectional view showing a cross section of a resonator according to a sixth embodiment.

FIG. 14 is a graph showing the temperature coefficient of frequency (TCF) corresponding to a change in the ratio of electrode layer thickness h/λ of the resonator shown in FIG. 13.

FIG. 15 is a cross-sectional view showing a cross section of a resonator according to a seventh embodiment.

FIG. 16 is a graph showing the temperature coefficient of frequency (TCF) corresponding to a change in the ratio of electrode layer thickness h/λ of the resonator.

FIG. 17 is an enlarged cross-sectional view showing an enlarged view of the electrode layer in the eighth embodiment.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

In the embodiments described below, the drawings are schematic. Accordingly, relationships between thickness and planar dimensions, ratios of thickness among the respective layers, and other dimensional relationships may differ from actual conditions. Moreover, differences may also exist among the drawings themselves with respect to relative dimensions and ratios.

### First Embodiment

FIG. 1 is a circuit configuration diagram of a transmit filter 10, which is a bandpass filter according to a first embodiment of the present invention.

As shown in FIG. 1, the transmit filter 10 functioning as a bandpass filter is a ladder-type filter and includes series resonators S1, S2, S3, S4, and S5 connected in series along a signal path extending from a transmit port (Tx) to an antenna port (Ant). Between the nodes connecting the series resonators S1, S2, S3, S4, and S5 and the ground, parallel resonators P1, P2, P3, and P4 are connected. Here, the term “node” refers to a connection point between circuit elements.

The first-stage series resonator is S1, and the final-stage series resonator is S5. The series resonator S2 includes divided resonators S21 and S22. Similarly, the series resonator S3 includes divided resonators S31 and S32.

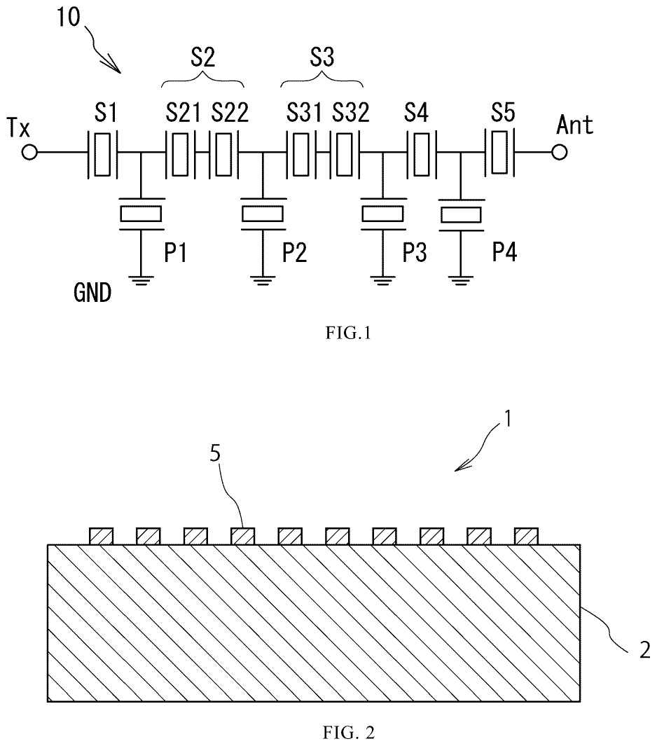

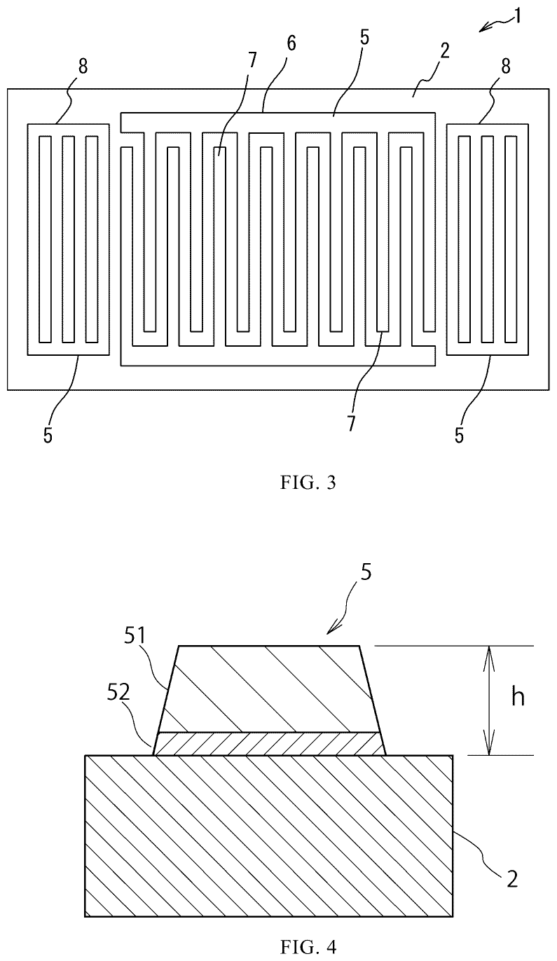

FIG. 2 is a cross-sectional view of a resonator constituting the bandpass filter according to the first embodiment of the present invention. More specifically, FIG. 2 illustrates a basic structure of the resonator 1, which represents the fundamental configuration of the above-described series resonators S1-S5 and parallel resonators P1-P4. The resonator 1 includes a piezoelectric layer 2 and an electrode layer 5 provided on the piezoelectric layer 2.

The piezoelectric layer 2 may be formed of, for example, 42° rotated Y-cut X-propagating lithium tantalate (LiTaO₃). However, the material is not limited thereto and may alternatively be made of other materials such as lithium niobate (LiNbO₃). The thickness of the piezoelectric layer 2 is, for example, 200 μm.

FIG. 3 is a top view of a resonator 1 constituting the bandpass filter according to the first embodiment. Specifically, the resonator 1 includes an interdigital transducer (IDT) electrode 6 and a reflector 8. More specifically, the IDT electrode 6 includes a plurality of electrode fingers 7. The IDT electrode 6 and the reflector 8 are formed by patterning the electrode layer 5.

FIG. 4 is an enlarged cross-sectional view showing an enlarged portion of the electrode layer of the resonator. The electrode layer 5 includes a first metal layer 51 and a second metal layer 52. Specifically, the first metal layer 51 is, for example, an alloy of aluminum and copper; the second metal layer 52 is, for example, titanium. The second metal layer 52 made of titanium serves as an adhesion layer for enhancing the bonding between the piezoelectric layer 2 and the first metal layer 51, and the thickness of the second metal layer 52 is, for example, 15 nm.

The total thickness of the first metal layer 51 and the second metal layer 52 constitutes the electrode layer thickness h of the electrode layer 5. In this embodiment, the electrode layer thickness h is classified into two types depending on each resonator: a thickness h1 defined by the wavelength λ, and a thinner thickness h2 than the thickness h1.

When the electrode layer thickness of a first resonator is defined as h1, and the electrode layer thickness of a second resonator is defined as h2, the following relationships (Equations 1 and 2) are satisfied:

$$0.09 \leq h 1 / λ \leq 0.1 \qquad ( Equation 1 )$$

$$0.05 \leq h 2 / λ \leq 0.075 \qquad ( Equation 2 )$$

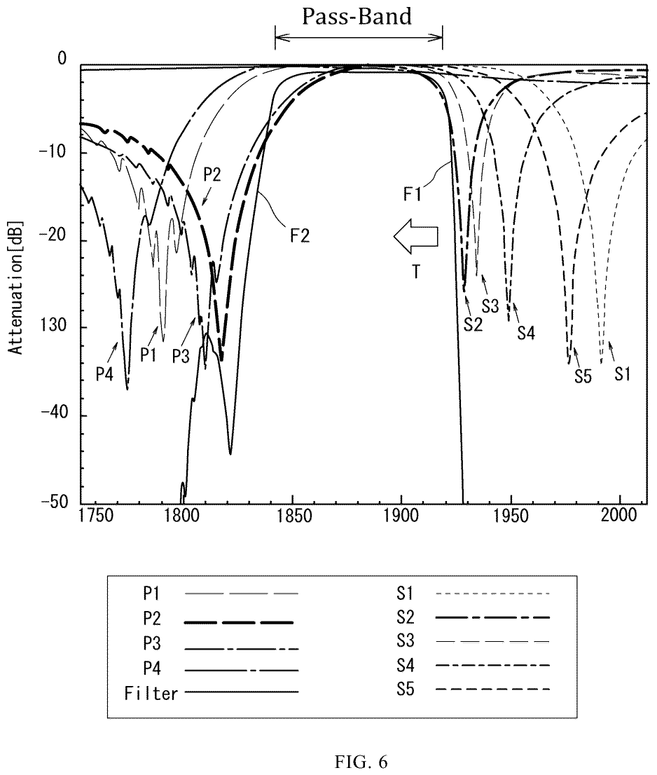

FIG. 6 is a graph showing the attenuation (in decibels) versus frequency characteristics of the transmit filter 10 functioning as the bandpass filter shown in FIG. 1, and the transmission characteristics (filter responses) of each resonator.

As shown in the graph, the passband of the transmit filter 10 is formed by the combined transmission characteristics of the respective resonators.

### Example 1

TABLE 1

| | | | | Anti- | | |
|---|---|---|---|---|---|---|
| | | | | resonant | Resonant | |
| | λ | h | h/λ | frequency | frequency | TCF |
| Resonator | [μm] | [nm] | [%] | [MHz] | [MHz] | [ppm/K] |
| S1 | 1.92 | 185 | 9.6 | 1992 | — | −53.1 |
| S21 | 2.01 | 130 | 6.5 | 1929 | — | −46.6 |
| S22 | 2.01 | 130 | 6.5 | 1929 | — | −46.6 |
| S31 | 1.97 | 185 | 9.4 | 1934 | — | −52.5 |
| S32 | 1.97 | 185 | 9.4 | 1934 | — | −52.5 |
| S4 | 1.95 | 185 | 9.5 | 1949 | — | −52.8 |
| S5 | 1.93 | 185 | 9.6 | 1976 | — | −53.1 |
| P1 | 2.05 | 185 | 9.0 | 1868 | 1791 | −51.2 |
| P2 | 2.03 | 185 | 9.1 | 1896 | 1818 | −51.5 |
| P3 | 2.04 | 185 | 9.1 | 1889 | 1810 | −51.5 |
| P4 | 2.05 | 185 | 9.0 | 1851 | 1775 | −51.2 |

Table 1 shows, for the transmit filter 10 of Example 1 in the first embodiment illustrated in FIG. 1, the wavelength λ defined by the pitch of each resonator, the electrode layer thickness h of the electrode layer 5 defined by λ, the normalized ratio h/λ [%], the resonant frequency, and the temperature coefficient of frequency (TCF).

In Table 1, a resonator in which the thickness h of the electrode layer 5 satisfies Equation (2) (0.050≤h2/λ≤0.075) is referred to as a “Second Resonator”. The second resonator having the electrode layer thickness h2 (130 nm) is the divided resonators S21 and S22, which are obtained by dividing the series resonator S2. The divided resonators S21 and S22 have a TCF of −46.6, which represents an improvement compared to other resonators such as S1.

Resonators other than these, whose electrode layer thickness h satisfies Equation (1) (0.09≤h1/λ≤0.10), are referred to as “first resonators.” In the first resonators, the TCF values are −51.2 to −53.1, showing close numerical values. The first resonators having the electrode layer thickness h1 (185 nm) include the series resonators S1, S31, S32, S4, and S5, and the parallel resonators P1 to P4. The electrode layer thickness h1 is defined by the wavelength λ, which in turn is determined by the electrode finger pitch of the IDT electrodes in each resonator.

The electrode layer thickness h2 of the second resonator, which satisfies Equation (2), is thinner than the electrode layer thickness h1 of the first resonator, which satisfies Equation (1).

In Table 1, resonators that are not labeled as divided resonators are non-divided resonators.

In addition, the passband for Examples 1 to 6 is between 1850 MHz and 1915 MHz.

In the resonator shown in FIG. 2, it has been confirmed through simulation that when the electrode layer thickness h of the electrode layer 5 is reduced to h2, the TCF is improved.

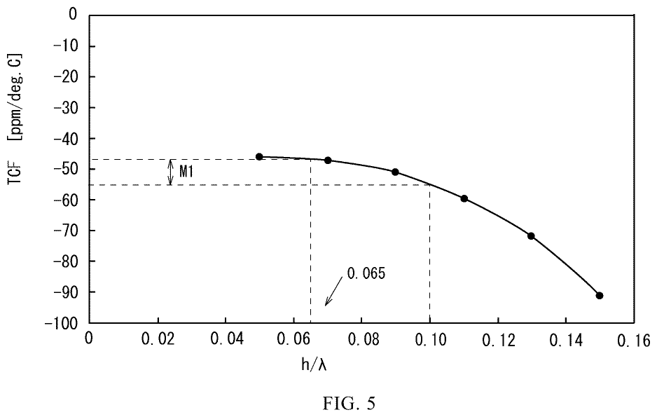

FIG. 5 shows the TCF variation in response to changes in the ratio of electrode layer thickness h/λ for a resonator in which the electrode layer 5 is formed on the piezoelectric layer 2, as shown in FIG. 2.

The simulation conditions are as follows:
Piezoelectric substrate: 42° rotated Y-cut X-propagating lithium tantalate (LiTaO₃)
Piezoelectric substrate thickness: 200 μm (100A)
Wavelength λ: 2 μm
Duty ratio: 50%

As shown in FIG. 5, when h/λ is reduced from 0.10 (10%) to 0.065 (6.5%), the absolute value of TCF decreases by the amount M1 shown in the figure. The difference M1 in improved numerical value is 8 ppm/K. That is, it can be seen that by thinning the electrode layer 5 from 0.1λ to 0.065λ, the TCF is improved.

In the graph of FIG. 6, which shows the attenuation with respect to frequency for the transmit filter 10 and each resonator, it is demonstrated that improving only the TCF of the series resonator S2 contributes to enhancing the power durability of the transmit filter 10 as a bandpass filter, while also suppressing an increase in its size. In the transmit filter 10, functioning as a bandpass filter, the portion F1 of the attenuation band on the higher-frequency side from the high-frequency end of the passband is dominantly determined by the series resonator S2. The next (second most contributing) resonator to the formation of portion F1 is the series resonator S3. In other words, the upper-right shoulder portion of the transmission characteristic curve is mainly influenced by the series resonator S2. The term “high-frequency end of the passband” refers to the highest-frequency side of the passband shown in FIG. 6.

Since the TCFs of the series resonators S2 to S5 are negative, when the temperature of each resonator increases during operation of the filter 10, the resonance frequencies shift in the direction of arrow T, that is, toward the lower-frequency side.

This shift of portion F1 toward the lower-frequency side means that the high-frequency end of the passband moves downward in frequency, resulting in signals that should normally pass being cut off instead.

When signals that should normally pass are blocked, losses occur, leading to heat generation in the resonators. As the amount of generated heat increases, the resonators overheat, causing a decrease in power durability. Therefore, it is desirable that the absolute value of TCF be as small as possible.

To reduce the absolute value of TCF, as shown in FIG. 5, the electrode layer 5 can be made thinner, for example, to 0.065λ. However, although the TCF is improved when the electrode layer 5 is thinned, the capacitance per unit area of the resonator in a planar view decreases. If all resonators in the transmit filter 10 were to have thin electrode layers 5, it would be necessary to increase the electrode or electrode layer area in the planar view to restore the original capacitance of the resonators. As a result, the planar area of each resonator would increase. Consequently, increasing the planar area of all resonators included in the bandpass filter would lead to a significant increase in the overall size of the bandpass filter.

Accordingly, in this embodiment, only the series resonator S2—which most strongly contributes to forming the portion F1 of the attenuation band on the high-frequency side from the high-frequency end of the passband—is provided with a thinner electrode layer 5 having a thickness h2, thereby improving the TCF. The other resonators retain the thicker electrode layer with thickness h1 instead of being thinned to h2. Thus, the movement of portion F1 during temperature rise can be effectively suppressed.

Regarding the issue of filter enlargement, only the area of the series resonator S2 increases, while the areas of other resonators remain unchanged, thereby suppressing overall size growth.

In this way, both improvement in power durability of the transmit filter 10 and suppression of the size increase of the bandpass filter can be achieved.

As described above, in Example 1, by improving the TCF through thinning the electrode layer 5 only of the series resonator S2 to the thickness h2, it is possible to achieve both improvement of the power durability of the transmit filter 10 as a bandpass filter and suppression of size increase.

Furthermore, by dividing the series resonator S2 into divided resonators S21 and S22 connected in series, the power durability is further improved.

As a result, it is possible to suppress the degradation in power durability of the series resonator S2 caused by thinning the electrode layer 5 to h2.

### Example 2

TABLE 2

| | | | | Anti- | | |
|---|---|---|---|---|---|---|
| | | | | resonant | Resonant | |
| | λ | h | h/λ | frequency | frequency | TCF |
| Resonator | [μm] | [nm] | [%] | [MHz] | [MHz] | [ppm/K] |
| S1 | 1.92 | 185 | 9.6 | 1992 | — | −53.1 |
| S2 | 2.01 | 130 | 6.5 | 1929 | — | −46.6 |
| S3 | 1.97 | 185 | 9.4 | 1934 | — | −52.5 |
| S4 | 1.95 | 185 | 9.5 | 1949 | — | −52.8 |
| S5 | 1.93 | 185 | 9.6 | 1976 | — | −53.1 |
| P1 | 2.05 | 185 | 9.0 | 1868 | 1791 | −51.2 |
| P2 | 2.03 | 185 | 9.1 | 1896 | 1818 | −51.5 |
| P3 | 2.04 | 185 | 9.1 | 1889 | 1810 | −51.5 |
| P4 | 2.05 | 185 | 9.0 | 1851 | 1775 | −51.2 |

Table 2 shows, for the transmit filter 10 of Example 2 in the first embodiment illustrated in FIG. 1, the wavelength λ defined by the pitch of each resonator, the electrode layer thickness h of the electrode layer 5 defined by A, the normalized ratio h/λ [%], the resonant frequency, and the temperature coefficient of frequency (TCF).

In Table 2, a resonator whose electrode layer 5 thickness h satisfies Equation (2) (0.050≤h2/λ≤0.075) is referred to as a “second resonator”. The second resonator having the electrode layer thickness h2 is the series resonator S2. The series resonator S2 has a TCF of −46.6, which represents an improvement compared to other resonators such as S1. Resonators other than this, whose electrode layer thickness h satisfies Equation (1) (0.09≤h1/λ≤0.10), are referred to as “first resonators.” In the first resonators having the electrode layer thickness h1, the TCF values range from −51.2 to −53.1, showing close values. The first resonators having the electrode layer thickness h1 include the series resonators S1 and S3-S5, as well as the parallel resonators P1-P4.

The thickness h1 is defined by the wavelength λ, which in turn is determined by the electrode finger pitch of the IDT electrodes in each resonator.

The electrode layer thickness h2 that satisfies Equation (2) is thinner than the electrode layer thickness h1 that satisfies Equation (1).

As shown in this Example 2, the present invention can also be applied to cases in which divided resonators are not employed in the series resonator configuration.

### Example 3

TABLE 3

| | | | | Anti- | | |
|---|---|---|---|---|---|---|
| | | | | resonant | Resonant | |
| | λ | h | h/λ | frequency | frequency | TCF |
| Resonator | [μm] | [nm] | [%] | [MHz] | [MHz] | [ppm/K] |
| S1 | 1.92 | 185 | 9.6 | 1992 | — | −53.1 |
| S21 | 2.01 | 130 | 6.5 | 1929 | — | −46.6 |
| S22 | 2.01 | 130 | 6.5 | 1929 | — | −46.6 |
| S31 | 1.95 | 185 | 9.5 | 1934 | — | −52.5 |
| S32 | 1.95 | 185 | 9.5 | 1934 | — | −52.5 |
| S4 | 1.97 | 185 | 9.4 | 1949 | — | −52.8 |
| S5 | 1.93 | 185 | 9.6 | 1976 | — | −53.1 |
| P1 | 2.05 | 185 | 9.0 | 1868 | 1791 | −51.2 |
| P2 | 2.09 | 130 | 6.2 | 1896 | 1818 | −46.4 |
| P3 | 2.04 | 185 | 9.1 | 1889 | 1810 | −51.5 |
| P4 | 2.05 | 185 | 9.0 | 1851 | 1775 | −51.2 |

Table 3 shows, for the transmit filter 10 of Example 3 in the first embodiment illustrated in FIG. 1, the wavelength λ defined by the pitch of each resonator, the electrode layer thickness h of the electrode layer 5 defined by A, the normalized ratio h/λ [%], the resonant frequency, and the temperature coefficient of frequency (TCF).

In this Example 3, the electrode layer 5 thicknesses of the divided resonators S21 and S22, which correspond to the series resonator S2, and the parallel resonator P2, are made thinner than h1 and set to h2. The electrode layer thicknesses 5 of the other resonators are h1. Equations (1) and (2), which define the relationships satisfied by the thicknesses h1 and h2, are the same as those in Example 1. The parallel resonator P2 has a resonant frequency located further on the lower-frequency side than the passband of the transmit filter 10, and is the closest to the low-frequency end of the bandpass filter's passband. Therefore, the parallel resonator P2 most significantly contributes to the formation of portion F2, which corresponds to the attenuation band on the lower-frequency side from the low-frequency end of the passband.

Since the electrode layer thickness h of the parallel resonator P2 is made thinner to h2, the TCF is improved.

Thus, the movement of portion F2 on the lower-frequency side of the passband during temperature rise can be effectively suppressed.

Moreover, since only some of the resonators have their electrode layers 5 thinned to h2, an increase in the size of the transmit filter 10 can be suppressed.

That is, both enhancement of power durability and suppression of size increase of the transmit filter 10 can be achieved.

Furthermore, similar to Example 1, since the electrode layer thickness h of the divided resonators S21 and S22 is made thinner to h2, the TCFs of the divided resonators S21 and S22 are improved.

Accordingly, the movement of portion F1 on the higher-frequency side during temperature rise can be efficiently suppressed, thereby enhancing the power durability of the transmit filter 10.

### Example 4

TABLE 4

| | | | | Anti- | | |
|---|---|---|---|---|---|---|
| | | | | resonant | Resonant | |
| | λ | h | h/λ | frequency | frequency | TCF |
| Resonator | [μm] | [nm] | [%] | [MHz] | [MHz] | [ppm/K] |
| S1 | 1.92 | 185 | 9.6 | 1992 | — | −53.1 |
| S21 | 2.01 | 130 | 6.5 | 1929 | — | −46.6 |
| S22 | 2.01 | 130 | 6.5 | 1929 | — | −46.6 |
| S31 | 2.00 | 130 | 6.5 | 1934 | — | −46.6 |
| S32 | 2.00 | 130 | 6.5 | 1934 | — | −46.6 |
| S4 | 1.95 | 185 | 9.5 | 1949 | — | −52.8 |
| S5 | 1.93 | 185 | 9.6 | 1976 | — | −53.1 |
| P1 | 2.05 | 185 | 9.0 | 1868 | 1791 | −51.2 |
| P2 | 2.03 | 185 | 9.1 | 1896 | 1818 | −51.5 |
| P3 | 2.04 | 185 | 9.1 | 1889 | 1810 | −51.5 |
| P4 | 2.05 | 185 | 9.0 | 1851 | 1775 | −51.2 |

Table 4 shows, for the transmit filter 10 of Example 4 in the first embodiment illustrated in FIG. 1, the wavelength λ defined by the pitch of each resonator, the electrode layer thickness h of the electrode layer 5 defined by A, the normalized ratio h/λ [%], the resonant frequency, and the temperature coefficient of frequency (TCF).

In this Example 4, in addition to the divided resonators S21 and S22 obtained by dividing the series resonator S2, which has the nearest anti-resonant frequency from the high-frequency end of the passband, the electrode layer thicknesses of the divided resonators S31 and S32 obtained by dividing the series resonator S3, which has the second-nearest anti-resonant frequency from the high-frequency end of the passband, are made thinner to h2.

The electrode layer thicknesses of the other resonators are h1.

Equations (1) and (2), which define the relationships satisfied by the thicknesses h1 and h2, are the same as those in Example 1.

Accordingly, by improving the TCF through thinning the electrode layers 5 to h2 only for the series resonators S2 (divided resonators S21 and S22) and S3 (divided resonators S31 and S32), it is possible to further enhance the power durability of the transmit filter 10 as a bandpass filter compared to Example 1.

Moreover, since only some of the resonators have their electrode layers 5 thinned to h2 while the other resonators maintain the thickness h1, the enlargement of the transmit filter 10 can be effectively suppressed.

It is preferable that the series resonators having the electrode layer thickness h2 thinner than h1 be positioned at stages other than the first and final stages.

Since thinning the electrode layer reduces power durability, it is undesirable to make the electrode layer of the first-stage series resonator S1 thinner to h2, because the first-stage resonator consumes the most power and requires high power durability.

If the thickness of the final-stage series resonator S5 is made thinner to h2, new impedance matching would be required, leading to the need for redesign and additional complexity.

By configuring the electrode layers of the divided resonators S21, S22, S31, and S32, to have the thinner thickness h2, these problems can be avoided, and reliability degradation due to reduced power durability and redesign effort can both be suppressed.

### Example 5

TABLE 5

| | | | | Anti- | | |
|---|---|---|---|---|---|---|
| | | | | resonant | Resonant | |
| | λ | h | h/λ | frequency | frequency | TCF |
| Resonator | [μm] | [nm] | [%] | [MHz] | [MHz] | [ppm/K] |
| S1 | 1.92 | 185 | 9.6 | 1992 | — | −53.1 |
| S21 | 2.01 | 130 | 6.5 | 1929 | — | −46.6 |
| S22 | 2.01 | 130 | 6.5 | 1929 | — | −46.6 |
| S31 | 2.00 | 130 | 6.5 | 1934 | — | −46.6 |
| S32 | 2.00 | 130 | 6.5 | 1934 | — | −46.6 |
| S4 | 1.95 | 185 | 9.5 | 1949 | — | −52.8 |
| S5 | 1.93 | 185 | 9.6 | 1976 | — | −53.1 |
| P1 | 2.05 | 185 | 9.0 | 1868 | 1791 | −51.2 |
| P2 | 2.09 | 130 | 6.2 | 1896 | 1818 | −46.4 |
| P3 | 2.04 | 126 | 6.2 | 1889 | 1810 | −46.4 |
| P4 | 2.05 | 185 | 9.0 | 1851 | 1775 | −51.2 |

Table 5 shows, for the transmit filter 10 of Example 5 in the first embodiment illustrated in FIG. 1, the wavelength λ defined by the pitch of each resonator, the electrode layer thickness h of the electrode layer 5 defined by A, the normalized ratio h/λ [%], the resonant frequency, and the temperature coefficient of frequency (TCF).

In Example 5, in addition to thinning the electrode layer 5 to the thickness h2 for the series resonator S2 (divided resonators S21 and S22), the series resonator S3 (divided resonators S31 and S32), and the parallel resonator P2 as in Example 4, the electrode layer 5 of the parallel resonator P3, which has the second-nearest resonant frequency from the low-frequency end of the passband, is further thinned to the thickness h2.

Accordingly, as in Example 4, by improving the TCF through thinning the electrode layer 5 of the series resonators S2 (divided resonators S21 and S22) and S3 (divided resonators S31 and S32) to h2, it is possible to further enhance the power durability of the transmit filter 10 as a bandpass filter.

Furthermore, in addition to the parallel resonator P2, whose electrode layer 5 was made thinner to h2 in Example 4, the electrode layer 5 of the parallel resonator P3 is also made thinner to h2 in this Example 5.

As a result, the TCF of the parallel resonator P3 is improved, and the movement of portion F2 on the low-frequency side of the passband during temperature rise can be suppressed more effectively than in Example 4.

Since only some of the resonators have their electrode layers 5 thinned to h2, an increase in the overall size of the transmit filter 10 can be suppressed.

Thus, both improvement in power durability and suppression of enlargement of the transmit filter 10 can be achieved.

### Example 6

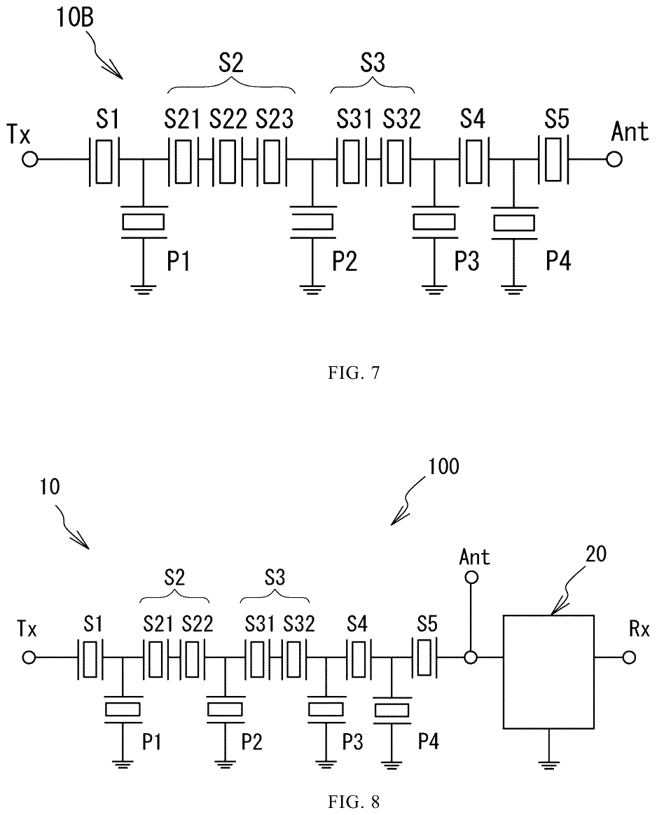

FIG. 7 is a circuit configuration diagram of the transmit filter 10B according to Example 6.

TABLE 6

| | | | | Anti- | | |
|---|---|---|---|---|---|---|
| | | | | resonant | Resonant | |
| | λ | h | h/λ | frequency | frequency | TCF |
| Resonator | [μm] | [nm] | [%] | [MHz] | [MHz] | [ppm/K] |
| S1 | 1.92 | 185 | 9.6 | 1992 | — | −53.1 |
| S21 | 2.01 | 130 | 6.5 | 1929 | — | −46.6 |
| S22 | 2.01 | 130 | 6.5 | 1929 | — | −46.6 |
| S23 | 2.00 | 130 | 6.5 | 1929 | — | −46.6 |
| S31 | 2.00 | 130 | 6.5 | 1934 | — | −46.6 |
| S32 | 2.01 | 130 | 6.5 | 1934 | — | −46.6 |
| S4 | 1.95 | 185 | 9.5 | 1949 | — | −52.8 |
| S5 | 1.93 | 185 | 9.6 | 1976 | — | −53.1 |
| P1 | 2.05 | 185 | 9.0 | 1868 | 1791 | −51.2 |
| P2 | 2.03 | 185 | 9.1 | 1896 | 1818 | −51.5 |
| P3 | 2.04 | 185 | 9.1 | 1889 | 1810 | −51.5 |
| P4 | 2.05 | 185 | 9.0 | 1851 | 1775 | −51.2 |

Table 6 shows, for the transmit filter 10B of Example 6, the wavelength λ defined by the pitch of each resonator, the electrode layer thickness h of the electrode layer 5 defined by A, the normalized ratio h/λ [%], the resonant frequency, and the temperature coefficient of frequency (TCF).

In this Example 6, the series resonator S2 is divided into three portions to form divided resonators S21, S22, and S23 that are connected in series.

Thus, by dividing the series resonator S2 into the divided resonators S21, S22, and S23 connected in series, power durability is improved.

As a result, it is possible to suppress the decrease in power durability of the series resonator S2 caused by making its electrode layer 5 thinner to the thickness h2.

Accordingly, both thinning of the resonator's electrode layer and maintaining power durability can be achieved simultaneously.

### Second Embodiment

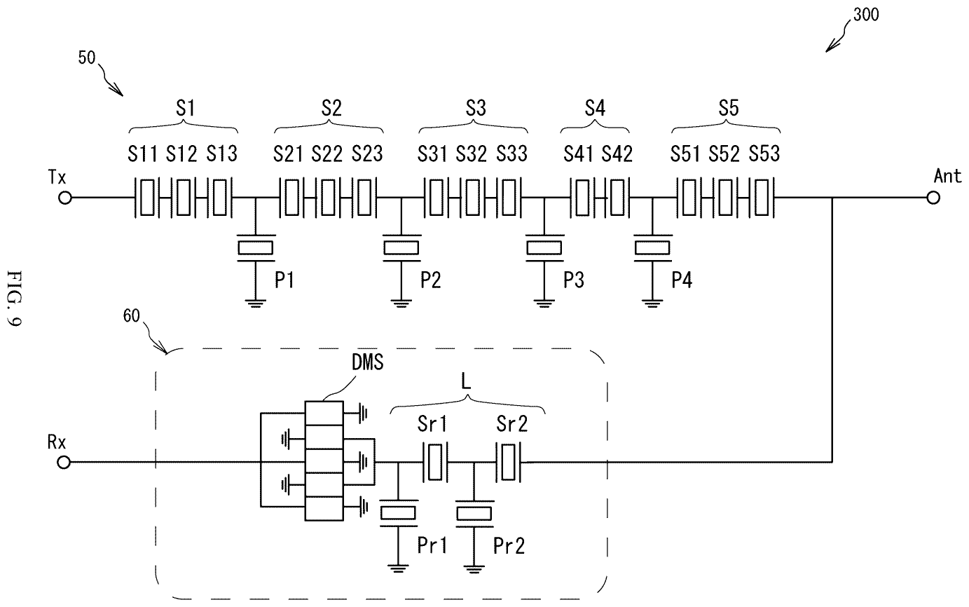

FIG. 8 is a circuit configuration diagram showing a duplexer 100 functioning as a multiplexer including the transmit filter 10 according to the first embodiment of the present invention.

As shown in FIG. 8, this duplexer 100 includes a transmit filter 10 serving as a bandpass filter and a receive filter 20.

For components having the same functions and names as those in the first embodiment, the same reference numerals are used and detailed description is omitted.

In this manner, a duplexer 100 equipped with the transmit filter 10 functioning as a bandpass filter according to the present invention can be configured.

Any of Examples 1 through 6 described above can be applied to the transmit filter 10.

### Third Embodiment

FIG. 9 is a circuit configuration diagram showing a duplexer including the receive filter 40 according to the third embodiment of the present invention.

This duplexer 200 includes a transmit filter 30 and a receive filter 40.

Both the transmit filter 30 and the receive filter 40 are ladder-type filters.

In the receive filter 40, as in Examples 1 through 6, the electrode layers 5 of some of the resonators may be thinned to h2.

Specifically, the electrode layer 5 may be made thinner to h2 only for the series resonator S7 (divided resonators S71 and S72) that most contributes to the formation of the attenuation band portion on the high-frequency side from the high-frequency end of the passband, or additionally for the series resonator S8 (divided resonators S81 and S82) that contributes second most.

Here, in the transmission characteristics corresponding to FIG. 6, the series resonator S2 in FIG. 6 corresponds to S7 in the receive filter 40, and S3 corresponds to S8; therefore, illustration is omitted.

Similarly, only the electrode layer 5 of the parallel resonator P6 (corresponding to the parallel resonator P2 in FIG. 6) that most contributes to the formation of the attenuation portion F2 on the low-frequency side from the low-frequency end of the passband, or additionally that of the parallel resonator P7 (corresponding to the parallel resonator P3 in FIG. 6) may be made thinner to h2.

### Fourth Embodiment

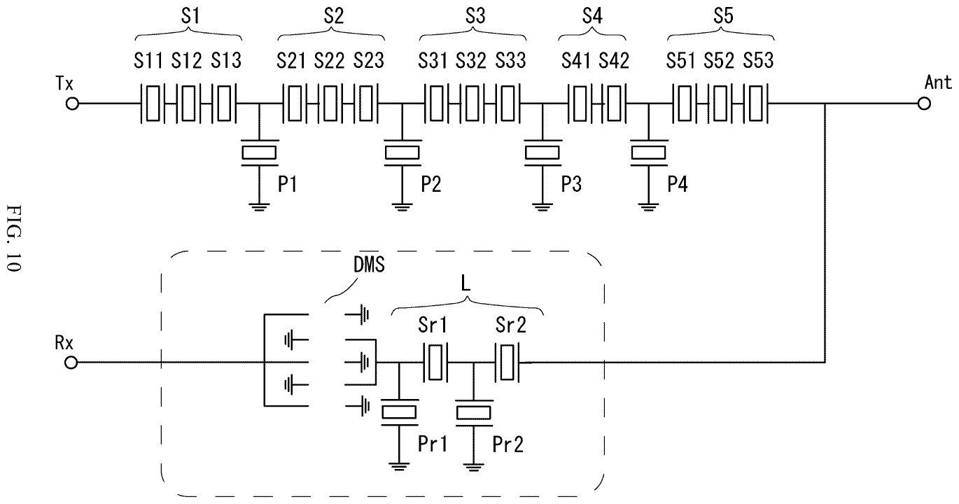

FIG. 10 is a circuit configuration diagram showing a duplexer 300 functioning as a multiplexer according to the fourth embodiment of the present invention.

This duplexer 300 includes a transmit filter 50 and a receive filter 60.

The transmit filter 50 is a ladder-type filter.

The receive filter 60 is a DMS-plus-ladder-type filter, in which a dual-mode SAW (DMS) filter and a ladder-type filter L are connected in series.

The ladder-type filter L is composed of series resonators Sr1, Sr2, and parallel resonators Pr1, Pr2.

In the receive filter 60 functioning as the DMS-plus-ladder-type filter, as in Examples 1 through 6, the electrode layer 5 thickness of at least the series resonator Sr1, and one or both of the parallel resonators Pr1 and Pr2, may be made thinner to h2 so that the present invention can be applied.

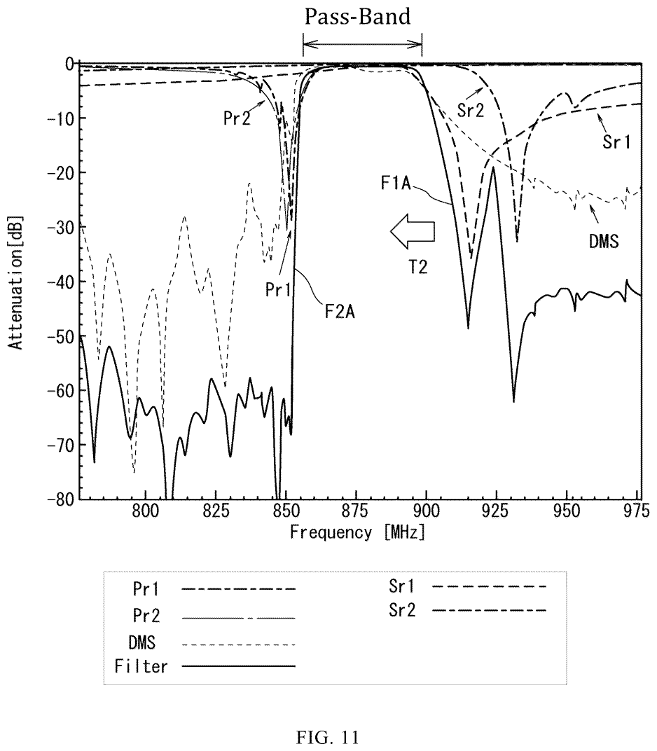

FIG. 11 shows the transmission characteristics of each resonator, a DMS, and a receive filter 60 as a DMS-plus-ladder-type filter shown in FIG. 10.

Among these, the resonator having the anti-resonant frequency nearest to the high-frequency end of the passband is the series resonator Sr1.

Therefore, Sr1 most contributes to the formation of the attenuation portion F1A from the high-frequency end of the passband.

Since this portion lies on the high-frequency side beyond the passband, the electrode layer 5 of Sr1 is thinned from its original thickness h1 to h2 to improve its TCF.

By improving the TCF of Sr1, the shift of the portion F1A toward the low-frequency side (as indicated by the arrow in FIG. 11) due to temperature rise can be suppressed.

Moreover, since only some of the resonators have thinned electrode layers, enlargement of the filter can be prevented.

The details of thicknesses h1 and h2 are the same as those in Table 1 of Example 1 and are therefore omitted.

The resonator having the second-nearest anti-resonant frequency from the high-frequency end of the passband is the series resonator Sr2, which thus contributes secondarily to the formation of portion F1A.

Therefore, the electrode layer 5 of Sr2 is also made thinner to h2 from its original thickness h1. In this way, the TCF of Sr2 can be improved.

Details of the thickness are the same as in Table 1 and are omitted.

In this embodiment, the electrode layer 5 of Sr2 is made thinner to h2, but it may alternatively remain at h1.

On the low-frequency side of the passband, the resonator having the nearest resonant frequency from the low-frequency end is the parallel resonator Pr1.

Therefore, Pr1 most contributes to forming the attenuation portion F2A extending from the low-frequency end of the passband.

In this embodiment, the electrode layer 5 of the parallel resonator Pr1 is made thinner to h2 from its original thickness h1, thereby improving its TCF.

By improving the TCF of Pr1, it is possible to suppress the shift of the portion F2A toward the low-frequency side (as indicated by the arrow in FIG. 11) during temperature rise.

Furthermore, since only some of the resonators have thinned electrode layers, enlargement of the filter can be suppressed.

### Fifth Embodiment

FIG. 12 is a circuit configuration diagram showing a transmit/receive filter (TRx filter) 400 according to the fifth embodiment of the present invention.

This transmit/receive filter 400 is a ladder-type filter in which series resonators S1, S2, S3, and S4 are connected in series between the transmit/receive port TRx and the antenna port Ant, and parallel resonators P1, P2, P3, and P4 are connected in parallel between these series resonators and ground. The parallel resonator P1 is connected to the node between the transmit/receive port TRx and the series resonator S1. The series resonator S2 is divided into divided resonators S21 and S22 connected in series, and the series resonator S3 is divided into divided resonators S31 and S32 connected in series.

The transmit/receive filter 400 is a filter that switches between transmission as a transmit filter and reception as a receive filter.

The present invention can also be applied to such a transmit/receive filter 400.

Specifically, a bandpass filter can be configured in which the electrode layer of the series resonator having the nearest anti-resonant frequency from the high-frequency end of the passband, or both that resonator and the one having the second-nearest anti-resonant frequency, is made thinner to h2.

As a result, by improving the TCF of those series resonators, the shift of the attenuation portion F1A from the passband to the attenuation band toward the low-frequency side due to temperature rise can be suppressed, preventing heat generation caused by loss and thereby improving power durability.

Furthermore, since only some of the resonators have thinned electrode layers, enlargement of the filter can be suppressed.

The details of the electrode layers 5 are the same as those in Examples 1 through 6 and are therefore omitted.

### Sixth Embodiment

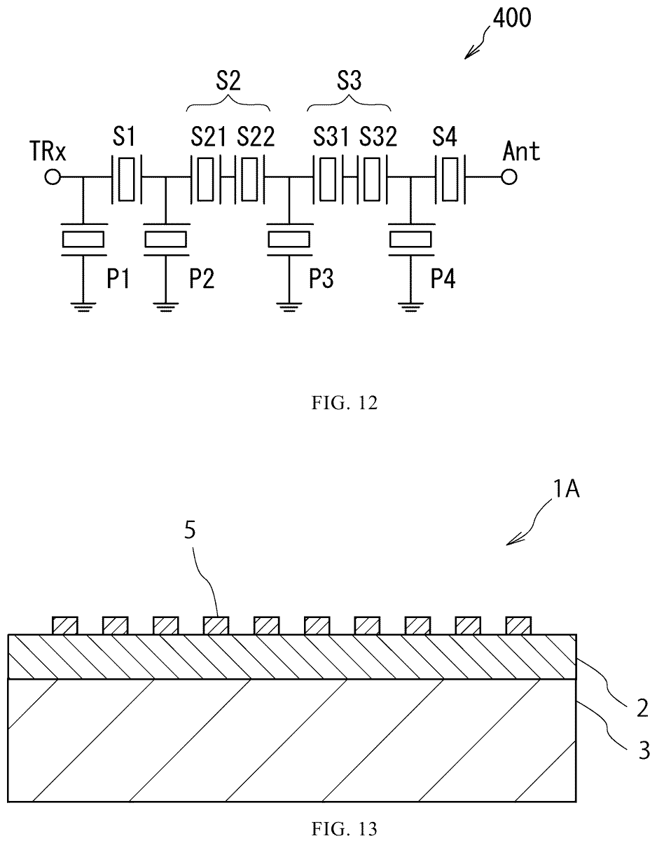

FIG. 13 is a sectional view of a resonator according to the sixth embodiment.

As shown in FIG. 13, the resonator 1A may include a support substrate 3 provided beneath the piezoelectric layer 2.

The support substrate 3 may be, for example, a spinel substrate, but other materials such as sapphire, silicon, quartz, alumina, or silicon carbide may also be used.

The thickness of the support substrate 3 is, for example, 200 μm.

In this embodiment, simulation confirms that TCF improves when the electrode layer 5 is thinned to h2.

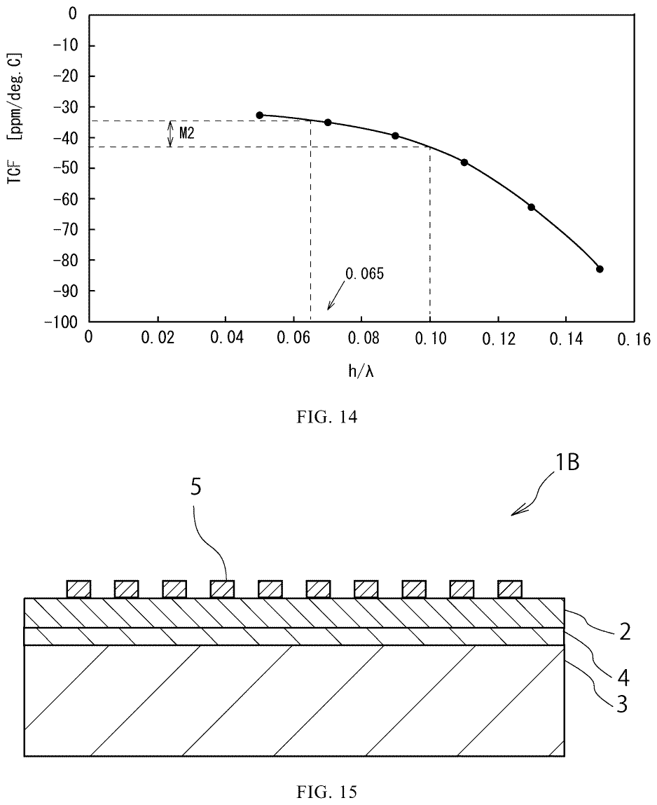

FIG. 14 shows the variation of TCF with respect to the change in h/λ for the resonator 1A having the support substrate 3, piezoelectric layer 2, and electrode layer 5.

Simulation conditions are as follows:
Piezoelectric substrate: 42° rotated Y-cut X-propagating lithium tantalate
Piezoelectric substrate thickness: 1.0 μm (0.5λ)
Support substrate: Spinel
Support substrate thickness: 200 μm
Wavelength λ: 2 μm
Duty ratio: 50%.

As shown in FIG. 14, when h/λ is reduced from 0.10 (10%) to 0.065 (6.5%), the absolute value of TCF decreases by the difference M2 shown in the figure, indicating improvement.

This improvement amount M2 is 9 ppm/K.

Thus, by thinning the electrode layer 5 from 0.1λ to 0.065λ, the TCF can be improved.

From the graph in FIG. 14, it can be concluded that thinning the electrode layer h improves TCF, and therefore the present invention is also applicable to resonators 1A having a support substrate 3 provided beneath the piezoelectric layer 2.

### Seventh Embodiment

FIG. 15 is a sectional view of a resonator according to the seventh embodiment.

As shown in FIG. 15, the resonator 1B may include an intermediate layer 4 provided between the piezoelectric layer 2 and the support substrate 3.

The intermediate layer 4 is, for example, silicon oxide (SiO₂).

The thickness of the support substrate 3 is, for example, 200 μm.

In this embodiment, simulation confirms that TCF improves when the electrode layer 5 is thinned to h2.

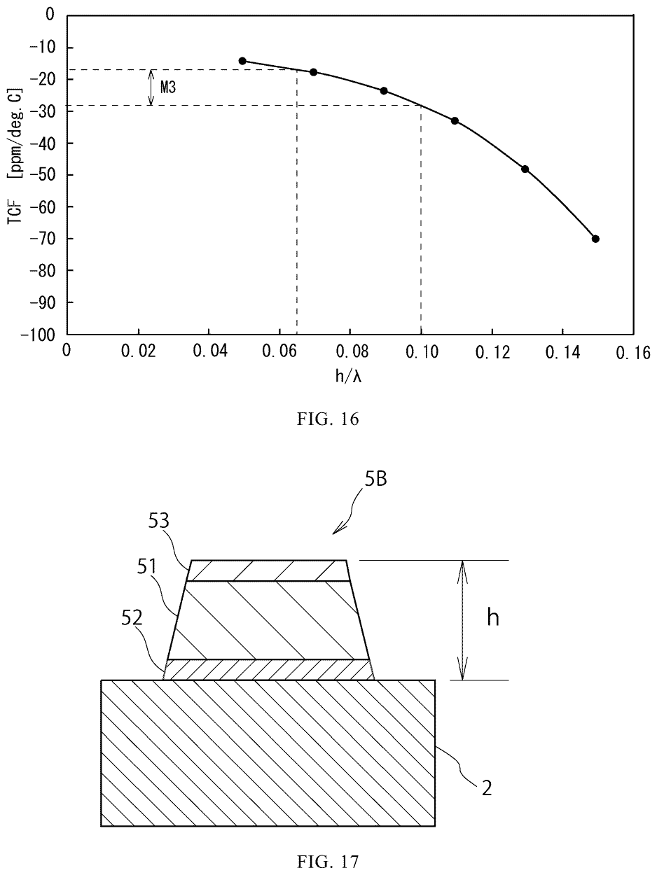

FIG. 16 shows the variation of TCF with respect to the change in h/λ for the resonator 1B having the support substrate 3, intermediate layer 4, piezoelectric layer 2, and electrode layer 5.

Simulation conditions are as follows:
Piezoelectric substrate: 42° rotated Y-cut X-propagating lithium tantalate
Piezoelectric substrate thickness: 0.6 μm (0.3λ)
Intermediate layer: Silicon oxide
Intermediate layer thickness: 1.0 μm (0.5λ)
Support substrate: Spinel
Support substrate thickness: 200 μm
Wavelength A: 2 μm
Duty ratio: 50%.

As shown in FIG. 16, when h/λ is reduced from 0.10 (10%) to 0.065 (6.5%), the absolute value of TCF decreases by the difference M3 shown in the figure, indicating improvement.

This improvement amount M3 is 11 ppm/K.

Thus, by thinning the electrode layer 5 from 0.1λ to 0.065λ, the TCF can be improved.

From the graph in FIG. 16, it can be concluded that the present invention is also applicable to the resonator 1B shown in FIG. 15, which includes the intermediate layer 4 between the piezoelectric layer 2 and the support substrate 3.

### Eighth Embodiment

FIG. 17 is an enlarged sectional view showing the electrode layer in the eighth embodiment.

This electrode layer 5B includes a first metal layer 51, a second metal layer 52, and a third metal layer 53.

The first metal layer is, for example, an aluminum-copper alloy.

The second metal layer is, for example, titanium.

The second metal layer 52 made of titanium serves as an adhesion layer to enhance bonding between the piezoelectric layer 2 and the first metal layer 51.

The third metal layer 53 has a thickness of, for example, 15 nm and is also titanium.

In the above embodiments, although the transmission characteristics of each resonator in the bandpass filter have been described, the resonator positions exhibiting such characteristics are not limited to these examples.

For instance, the transmission characteristics of the series resonators S2 and S3 may be interchanged.

In the embodiments described above, the bandpass filter of the present invention has been explained as being used in a transmit filter, but it may also be applied to a receive filter.

Furthermore, the bandpass filter of the present invention may be applied to both the transmit and receive filters in a duplexer.

Although the embodiments above describe using the bandpass filter of the present invention in a duplexer, the application is not limited to duplexers.

It may also be applied to other multiplexers such as triplexers or quadplexers, either partially or entirely incorporating the bandpass filters of the present invention.

While the present invention has been described in detail above, the specific embodiments of the bandpass filter and multiplexer are not limited to these examples, and various modifications and additions may be made without departing from the scope of the invention.

What is claimed is:

1. A bandpass filter having a passband, comprising:
a piezoelectric substrate; and
a plurality of resonators formed on the piezoelectric substrate;
wherein the plurality of resonators include IDT electrodes composed of electrode layers provided on the piezoelectric substrate;
wherein the plurality of resonators include a first resonator having a first electrode layer thickness h1, and a second resonator having a second electrode layer thickness h2, wherein h2<h1; and,
among the plurality of resonators, the resonator whose anti-resonant frequency lies on the higher-frequency side of the passband and is closest to the high-frequency end of the passband, has the electrode layer thickness h2.

2. The bandpass filter according to claim 1, further comprising a resonator whose anti-resonant frequency lies on the higher-frequency side of the passband and is second-closest to the high-frequency end of the passband, the resonator having the second electrode layer thickness h2.

3. The bandpass filter according to claim 1, further comprising a resonator whose resonant frequency lies on the lower-frequency side of the passband and is closest to the low-frequency end of the passband, the resonator having the second electrode layer thickness h2.

4. The bandpass filter according to claim 1, further comprising a resonator whose resonant frequency lies on the lower-frequency side of the passband and is second-closest to the low-frequency end of the passband, the resonator having the second electrode layer thickness h2.

5. The bandpass filter according to claim 1, wherein the first electrode layer thickness h1 and the second electrode layer thickness h2 satisfy:
$$0.09 \leq h 1 / λ \leq 0.1 \qquad ( 1 )$$
$$0.05 \leq h 2 / λ \leq 0.075 \qquad ( 2 )$$
wherein A is a wavelength defined by an electrode finger pitch of the IDT electrodes.

6. The bandpass filter according to claim 1, wherein at least one of the resonators having the electrode layer thickness h2 is configured as a divided resonator, in which the resonator is divided into a plurality of resonator sections of the same electrode layer thickness and connected in series.

7. The bandpass filter according to claim 1, wherein the bandpass filter is a ladder-type filter having at least three stages.

8. The bandpass filter according to claim 1, comprising a multi-mode surface acoustic wave filter and a ladder-type filter connected in series with the multi-mode surface acoustic wave filter, wherein the ladder-type filter includes a series resonator and a parallel resonator.

9. The bandpass filter according to claim 1, comprising a plurality of series resonators with a first-stage series resonator and a last-stage series resonator, wherein the resonator having the electrode layer thickness h2 is not the first-stage or last-stage series resonator among the plurality of series resonators.

10. The bandpass filter according to claim 1, wherein the passband is between 1850 MHz and 1915 MHz.

11. The bandpass filter according to claim 1, further comprising a support substrate provided beneath the piezoelectric layer.

12. The bandpass filter according to claim 1, further comprising an intermediate layer provided between the piezoelectric layer and the support substrate.

13. The bandpass filter according to claim 1, wherein the electrode layer includes a first metal layer, a second metal layer and a third metal layer.

14. A multiplexer comprising the bandpass filter according to claim 1.

15. The multiplexer according to claim 14, comprising a transmit filter serving as the bandpass filter and a receive filter.

16. A duplexer comprising the bandpass filter according to claim 1.

17. The duplexer according to claim 16, comprising a transmit filter and a receive filter.

18. The duplexer according to claim 17, wherein both the transmit filter and the receive filter are ladder-type filters.

19. The duplexer according to claim 17, wherein the transmit filter is a ladder-type filter, and the receive filter includes a multi-mode acoustic wave filter and a ladder-type filter connected in series with the multi-mode acoustic wave filter, wherein the ladder-type filter includes a series resonator and a parallel resonator.

20. The duplexer according to claim 19, wherein at least one of the resonators have the electrode layer thickness h2.
